(19) United States
(12) Patent Application Publication
(10) Pub. No.: US 2008/0181099 A1
(43) Pub. Date: Jul. 31, 2008

(54) Methods, systems, and computer program products for using alarm data correlation to automatically analyze a network outage

(76) Inventors: Homayoun Torab, Lawrenceville, GA (US); Mounire El Houmaidi, Atlanta, GA (US)

Correspondence Address: CANTOR COLBURN LLP - BELLSOUTH, 20 Church Street, 22nd Floor, Hartford, CT, 06103, US

(21) Appl. No.: 11/657,886

(22) Filed: Jan. 25, 2007

(51) Int. Cl. G01R 31/08

(52) U.S. Cl. 370/216

(57) ABSTRACT

Using alarm data correlation to automatically analyze a network outage. Alarm data for a communications network is received. The received alarm data is correlated to determine a number of users affected by the outage. A set of rules are applied to the correlated alarm data to identify at least one root cause for the outage, and to determine whether or not a trouble ticket will be automatically generated for the outage.

### BACKGROUND

The present disclosure relates generally to communications networks and, more particularly, to methods, systems, and computer program products for using alarm data correlation to automatically analyze a network outage.

Communication networks are expected to provide reliable, consistent service even when environmental conditions are hostile, unpredictable, and rapidly changing. During network outages, such as those encountered during storms, service technicians utilize electronically gathered outage data to perform network verification and recovery. Outage information includes alarm data such as remote terminal/digital loop carrier (RT/DLC) system failures, digital loop carriers (DLCs) without commercial power, failed asymmetric digital subscriber line (ADSL) equipment, broadband customer out of service (OOS), simplex and failed carrier systems, signaling system seven (SS7) links affected, central offices (COs) on emergency generator or battery power, as well as data characterizing other types of alarm conditions.

Alarm data generated for a network may be gathered and centralized using a commercial software package such as the Telcordia Network Monitoring and Analysis (NMA) System. During an outage, a group of service technicians may analyze alarm data in the form of hundreds of individual alarm events gathered by NMA to determine at least one root cause for the outage. For example, the root cause of an outage may be a cut fiber optic cable, equipment failure, power failure, or other factors. After the root cause of an outage is determined, a service technician manually generates a trouble ticket in a broadband outage notification system (BONS) or other report generation system.

Trouble ticket generation is a time consuming process, typically taking fifteen to twenty minutes or longer. During this time, incoming calls will be received from customers who are no longer able to receive communication services over the network. These calls are handled by help desk agents who are not yet aware of the network outage, and who may attempt to guide the customer through long, tedious, and ultimately fruitless troubleshooting procedures. Once the trouble ticket is generated, help desk agents are informed of the network outage. At this time, help desk agents are able to provide appropriate guidance to incoming callers concerning the existence of a known outage and an estimated repair time for the outage. Using live help desk agents is an expensive proposition, costing approximately $5 to $10 or more per call. Moreover, additional costs are associated with service technicians who must print and examine numerous trouble tickets to identify an outage and determine its root cause.

Current network outage reporting methods are expensive and not scalable expanding networks. If an increased customer load must be handled, increased operational expenditures are required for hiring additional help desk personnel and additional service technicians. In view of the foregoing considerations, it would be desirable to have an automated system that collects alarm data from a communications network and analyzes the data to automatically generate a trouble ticket for a network outage.

### SUMMARY

Embodiments include methods, systems, and computer program products for using alarm data correlation to automatically analyze a network outage. The methods include receiving alarm data for a communications network. The received alarm data is correlated to determine a number of users affected by the outage. A set of rules are applied to the correlated alarm data to identify at least one root cause for the outage, and to determine whether or not a trouble ticket will be automatically generated for the outage.

Embodiments further include computer program products for implementing the foregoing methods.

Additional embodiments include a system for using alarm data correlation to automatically analyze a network outage. The system includes an alarm analysis mechanism for receiving alarm data associated with a communications network. The alarm analysis mechanism is capable of correlating the received alarm data to determine a number of users affected by the outage, applying a set of rules to the correlated alarm data to identify at least one root cause for the outage, and determining whether or not a trouble ticket will be automatically generated for the outage based upon the identified root cause. A rules database for storing the set of rules and an alarm database for storing alarm data are operably coupled to the alarm analysis mechanism. At least one of a user network interface database, a network topology database, or a telephone number to common language location identifier (CLLI) database are operably coupled to the alarm analysis mechanism. The user network interface database stores data associating each of a plurality of user identifiers with one or more corresponding network interface equipment identifiers. The network topology database stores a set of attributes associated with each of a plurality of network elements. The telephone number to CLLI mapping database associates each of a plurality of respective telephone numbers with a corresponding CLLI. A trouble ticket output mechanism is operatively coupled to the alarm analysis mechanism. The trouble ticket output mechanism is capable of at least one of printing a generated trouble ticket or displaying a generated trouble ticket.

Other systems, methods, and/or computer program products according to embodiments will be or become apparent to one with skill in the art upon review of the following drawings and detailed description. It is intended that all such additional systems, methods, and/or computer program products be included within this description, be within the scope of the present invention, and be protected by the accompanying claims.

### BRIEF DESCRIPTION OF DRAWINGS

Referring now to the drawings wherein like elements are numbered alike in the several FIGURES:

FIG. 1 depicts an illustrative system for using alarm data correlation to automatically analyze a network outage.

FIG. 2 shows a first illustrative method for using alarm data correlation to automatically analyze a network outage.

FIG. 3 shows a second illustrative method for using alarm data correlation to automatically analyze a network outage.

The detailed description explains exemplary embodiments of the invention, together with advantages and features, by way of example with reference to the drawings.

### DETAILED DESCRIPTION OF EXEMPLARY EMBODIMENTS

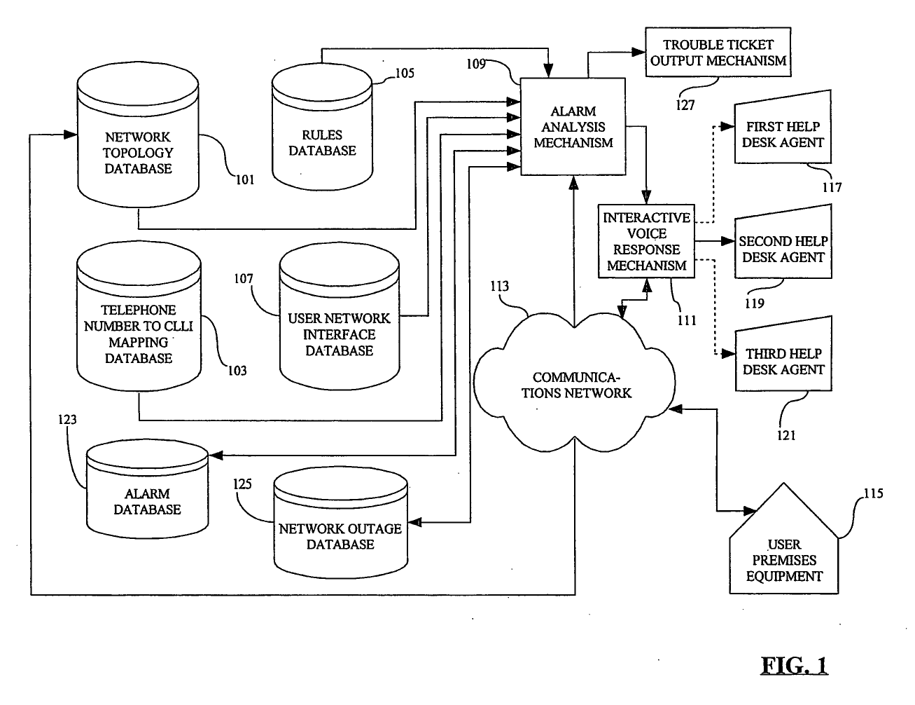

FIG. 1 depicts an illustrative system for using alarm data correlation to automatically analyze a network outage on a communications network 113. Communications network 113 may be implemented using any of a variety of networks and network components including, but not limited to, routers, switches, servers, the public switched telephone network (PSTN), a global network such as the Internet, a cable television network, a wide area network (WAN), a local area network (LAN), a virtual private network (VPN), a wireless network, a satellite communications network or the like, as well as various combinations thereof. These networks and network components are equipped to communicate using one or more protocols which, for purposes of illustration, could but need not include digital subscriber line (DSL), Internet protocol (IP), WiFi (IEEE 802.11), or WiMax (IEEE 802.16). For example, one illustrative implementation for communications network 113 may include the PSTN providing voice and broadband services over a DSL connection to a user premises equipment 115. An alarm analysis mechanism 109 is capable of receiving alarm data associated with communications network 113. Alarm analysis mechanism 109 is also capable of correlating the received alarm data to determine a number of users affected by the outage, applying a set of rules to the correlated alarm data to identify at least one root cause for the outage, and determining whether or not a trouble ticket will be automatically generated for the outage based upon the identified root cause. Illustratively, alarm analysis mechanism 109 is implemented using a network management system (NMS), general-purpose computer, personal computer, laptop computer, microprocessor-based device, server, personal digital assistant, computer network, or any of various combinations thereof. Regardless of the specific device or devices used to implement alarm analysis mechanism 109, this mechanism executes one or more computer programs for carrying out the processes described herein.

Alarm analysis mechanism 109 accesses information stored in a computer-readable storage medium to correlate received alarm data, determine a number of users affected by the outage, apply a set of rules to the correlated alarm data to identify at least one root cause for the outage, and determine whether or not a trouble ticket will be automatically generated for the outage based upon the identified root cause. Illustratively, this computer-readable storage medium is provided in the form of a network topology database 101, a telephone number to common language location identifier (CLLI) mapping database 103, a rules database 105, a user network interface database 107, an alarm database 123, and a network outage database 125. These databases are shown for illustrative purposes, as two or more of the databases may be combined into a single database, or one or more of the databases may be divided into additional databases. Moreover, one or more of these databases may be implemented using a computer-readable storage mechanism that is incorporated into alarm analysis mechanism 109. Databases in addition to those shown in FIG. 1 may be provided, and not all of the databases shown in FIG. 1 are required, so long as at least one database is provided in the form of a discrete element or as part of alarm analysis mechanism 109.

In the example of FIG. 1, rules database 105 and alarm database 123 are operably coupled to alarm analysis mechanism 109. Rules database 105 stores a set of rules to be applied to received alarm data, and alarm database 123 stores alarm data pertaining to communications network 113. Alarm data may be acquired and stored in alarm database 123 using a commercially available network monitoring software package such as Telcordia Network Monitoring and Analysis (NMA) System, or software developed specifically for and/or by a network service provider may be employed. Alarm database 123 may include alarm data acquired from one or more sources. In exemplary embodiments, all of the alarm data can be generated by a single alarm data source. In alternate exemplary embodiments, different kinds of errors are generated by different alarm data sources. In addition, errors for different kinds of conditions and/or equipment may be generated by different alarm data sources. For example, alarms related to digital loop carrier (DLC) equipment may be received from a first alarm data source such as the Telcordia NMA system, and alarms related to asymmetric digital subscriber lines (ADSLs) may be received from a second alarm data source specific to a given network service provider.

User network interface database 107 and network outage database 125 are operably coupled to alarm analysis mechanism 109. User network interface database 107 stores data associating each of a plurality of user identifiers with one or more corresponding network interface equipment identifiers. These network equipment identifiers illustratively identify equipment used at one or more network access nodes. Such equipment may, but need not, include DSLAMs, asynchronous transfer mode (ATM) switches, edge aggregators such as BRAS, and gateway devices.

Alarm analysis mechanism 109 correlates received alarm data stored in alarm database 123 to identify one or more network outages. Once a network outage is identified, details regarding the outage are stored in network outage database 125. These details may include one or more CLLIs associated with the network outage, equipment identifiers for equipment associated with the outage, a root cause for the outage, and optionally, a predicted or expected duration for the outage.

User premises equipment 115 may, but need not, be connected to communications network 113 in a manner so as to provide a first communications path and a second communications path, such that the first communications path is operable in the event that a network outage causes the second communications path to become inoperable. For example, the first communications path may be provided in the form of a wired or wireless telephonic connection which permits voice communication to take place between user premises equipment 115 and interactive voice response mechanism 111 over communications network 113 in the event that a network outage on network 113 temporarily disables data communications and Internet access for user premises equipment 115. In this manner, a user experiencing difficulty in accessing the Internet over communications network 113 may place a call over a wired or wireless telephonic device to interactive voice response mechanism 111 to receive automated assistance.

If there are no network outages affecting the user as indicated by a search of network outage database 125, interactive voice response mechanism 111 may guide the user through an automated troubleshooting session. If the automated troubleshooting session fails to resolve the difficulty experienced by the user, the call is forwarded to a help desk agent such as a first help desk agent 117, a second help desk agent 119, or a third help desk agent 121, so that the user may receive live assistance. On the other hand, if there are network outages affecting the user as indicated by a search of network outage database 125, the call is forwarded directly to a help desk agent such as first, second, or third help desk agents 117, 119, 121.

First, second, and third help desk agents 117, 119, 121 may each represent one or more communication devices used by human help desk operators, such as telephone handsets, computer terminals, or both. Alternatively or additionally, first, second, and third help desk agents 117, 119, 121 may each represent automated computerized help desk agents or bots.

A bot (short for “robot”) is a program that operates as an agent for a user by simulating a human activity. A chatterbot is a program that can simulate talk with a human being. For example, “Red” and “Andrette” are the names of two chatterbot programs that may be customized to answer questions from customers seeking assistance in connection with a product or service. Chatterbot programs are sometimes referred to as virtual representatives or virtual service agents.

Illustratively, first help desk agent 117 has expertise in a first area, second help desk agent 119 has expertise in a second area, and third help desk agent 121 has expertise in a third area. For example, first help desk agent 117 may be capable of answering questions related to customer problems in accessing a designated website over the Internet. Second help desk agent 119 may be capable of answering questions pertaining to weather-related network outages, and help desk agent 121 may be capable of answering questions related to internet protocol television (IPTV) problems. These areas of expertise are presented only for explanatory purposes.

Network topology database 101 is operably coupled to alarm analysis mechanism 109. Network topology database 101 stores a set of attributes associated with each of a plurality of network elements. These attributes identify one or more network platforms, products, type of products, DSL parameters, and/or common language location identifiers (CLLIs) associated with each of a plurality of elements in communications network 113.

Telephone number to common language location identifier (CLLI) database 103 is operably coupled to alarm analysis mechanism 109. Telephone number to CLLI mapping database 103 associates each of a plurality of respective telephone numbers with a corresponding CLLI. Telephone number to CLLI mapping database 103 permits an incoming service call received from user premises equipment 115 to be matched with a corresponding CLLI. After a user is matched with a corresponding CLLI, a search may be performed to identify any network outage problems associated with that CLLI.

A trouble ticket output mechanism 127 is operatively coupled to alarm analysis mechanism 109. Trouble ticket output mechanism 127 is capable of at least one of printing a generated trouble ticket or displaying a generated trouble ticket. Alarm analysis mechanism 109 applies a set of rules in rules database 105 to correlated alarm data from alarm database 123 to determine whether or not a trouble ticket will be generated automatically in response to received alarm data. If alarm analysis mechanism 109 determines that a trouble ticket should be generated based upon application of the rules to the correlated alarm data, then alarm analysis mechanism 109 activates trouble ticket output mechanism 127 to generate a trouble ticket. The trouble ticket may be stored electronically in network outage database 125.

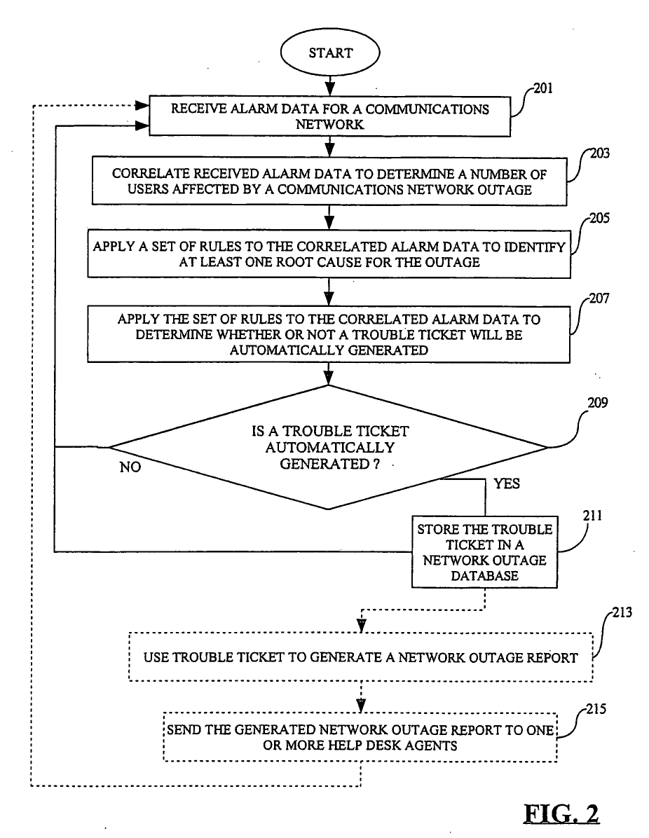

FIG. 2 shows a first illustrative method for using alarm data correlation to automatically analyze a communications network outage. The procedure commences at block 201 where alarm data is received for communications network 113 (FIG. 1). The received alarm data is correlated to determine a number of users affected by the outage (FIG. 2, block 203). This correlation may be performed by alarm analysis mechanism 109 (FIG. 1), and the received alarm data may be stored in alarm database 123. Next, at block 205 (FIG. 2), a set of rules are applied to the correlated alarm data to identify at least one root cause for the outage. These rules may be retrieved from rules database 105 (FIG. 1) by alarm analysis mechanism 109. Alarm analysis mechanism 109 may store details regarding the outage in network outage database 125. These details may include one or more CLLIs associated with the network outage, equipment identifiers for equipment associated with the outage, the root cause of the outage, and optionally, a predicted or expected duration for the outage. The set of rules are applied to the correlated alarm data to determine whether or not a trouble ticket will be automatically generated (FIG. 2, block 207).

Illustrative examples of root causes include cut or broken communication cables, an inoperative wireless communication link, failed equipment, a failed satellite link, a natural disaster that disables equipment at one or more specific central offices or CLLIs, or any of various other types of failures. Illustrative examples of rules specify that a trouble ticket will be generated if an outage affects at least a predetermined number of users, or if an outage is determined to be a high impact outage, or both. A high impact outage is an outage that is caused by one or more failed line cards in DSLAM or BRAS equipment, or one or more failed asynchronous transfer mode (ATM) cards in an ATM switch, or any of various other types of equipment failures that may affect a plurality of users.

At block 209 (FIG. 2), a test is performed to ascertain whether or not a trouble ticket should be automatically generated based upon the set of rules retrieved from rules database 105 (FIG. 1). If not, the procedure loops back to block 201 (FIG. 2). The affirmative branch from block 209 leads to block 211 where the trouble ticket is stored in network outage database 125 (FIG. 1). Additionally or alternatively, the trouble ticket may be outputted by trouble ticket output mechanism 127. The procedure then loops back to block 201 (FIG. 2) or, optionally, blocks 213 and 215 may be performed.

At optional block 213, the trouble ticket is used to generate a network outage report. Next, at optional block 215, the generated network outage report is sent to one or more help desk agents such as first, second, and third help desk agents 117, 119, 121 (FIG. 1). In this manner, help desk agents 117, 119, 121 may use information included in the network outage report to answer inquiries and requests for help received from users.

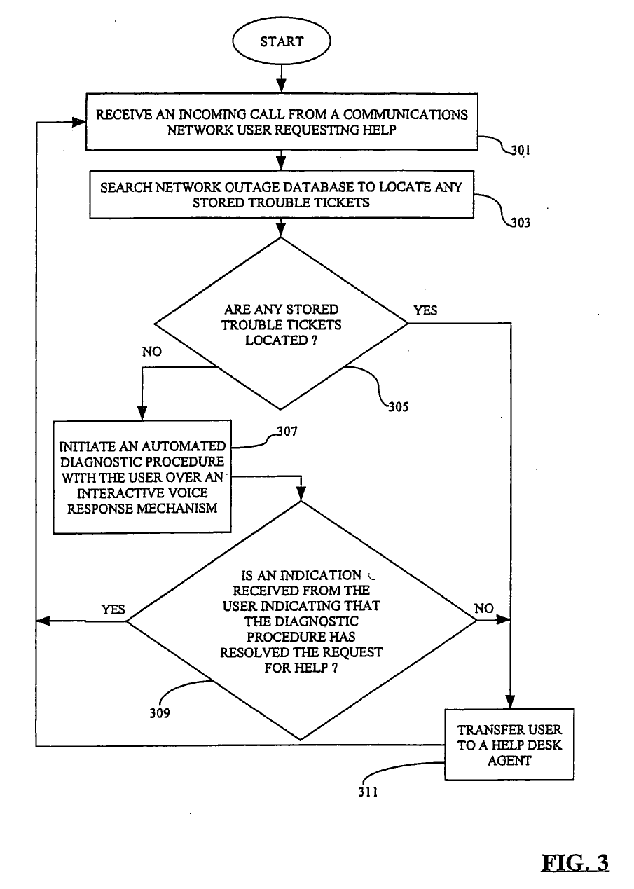

FIG. 3 shows a second illustrative method for using alarm data correlation to automatically analyze a network outage. This method may, but need not, be utilized in conjunction with the procedure of FIG. 2. Referring now to FIG. 3, an incoming call requesting help is received from a communications network user (block 301). A search is performed of network outage database 125 (FIG. 1) to locate any stored trouble tickets (FIG. 3, block 303). A test is performed at block 305 to ascertain whether or not any stored trouble tickets were located. If so, the procedure advances to block 311 where the call is transferred to a help desk agent such as first, second or third help desk agents 117, 119, 121 (FIG. 1).

The negative branch from block 305 (FIG. 3) leads to block 307 where an automated diagnostic procedure is initiated with the user over interactive voice response mechanism 111 (FIG. 1). A test is performed at block 309 (FIG. 3) to ascertain whether or not an indication is received from the user indicating that the diagnostic procedure has resolved the request for help. If so, the procedure loops back to block 301. The negative branch from block 309 leads to block 311 where the call is transferred to a help desk agent such as first, second, or third help desk agents 117, 119, 121 (FIG. 1).

As described above, the present invention can be embodied in the form of computer-implemented processes and apparatuses for practicing those processes. The present invention can also be embodied in the form of computer program code containing instructions embodied in tangible media, such as floppy diskettes, CD ROMs, hard drives, or any other computer-readable storage medium, wherein, when the computer program code is loaded into and executed by a computer, the computer becomes an apparatus for practicing the invention. The present invention can also be embodied in the form of computer program code, for example, whether stored in a storage medium, loaded into and/or executed by a computer, or transmitted over some transmission medium, loaded into and/or executed by a computer, or transmitted over some transmission medium, such as over electrical wiring or cabling, through fiber optics, or via electromagnetic radiation, wherein, when the computer program code is loaded into an executed by a computer, the computer becomes an apparatus for practicing the invention. When implemented on a general-purpose microprocessor, the computer program code segments configure the microprocessor to create specific logic circuits.

While the invention has been described with reference to exemplary embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiments disclosed for carrying out this invention, but that the invention will include all embodiments falling within the scope of the claims. Moreover, the use of the terms first, second, etc. do not denote any order or importance, but rather the terms first, second, etc. are used to distinguish one element from another. Furthermore, the use of the terms a, an, etc. do not denote a limitation of quantity, but rather denote the presence of at least one of the referenced item.

What is claimed is:

1. A method for using alarm data correlation to automatically analyze a network outage, the method including:
receiving alarm data for a communications network;
correlating the received alarm data to determine a number of users affected by the outage;
applying a set of rules to the correlated alarm data to identify at least one root cause for the outage, and to determine whether or not a trouble ticket will be automatically generated for the outage.

2. The method of claim 1 wherein the root cause includes at least one of:
a cut or broken communication cable;
an inoperative wireless communication link;
failed network equipment;
a failed satellite link; or
a natural disaster that disables equipment at one or more central offices or CLLIs or both.

3. The method of claim 1 wherein the set of rules specify that a trouble ticket will be generated if an outage affects at least a predetermined number of users, or if an outage is determined to be a high impact outage, or both.

4. The method of claim 3 wherein a high impact outage is an outage that is caused by at least one failed line card in DSLAM or BRAS equipment, or at least one failed asynchronous transfer mode (ATM) card in an ATM switch, or both.

5. The method of claim 1 further including receiving an incoming call from a communications network user requesting help, and searching a network outage database to locate any stored trouble tickets.

6. The method of claim 5 wherein, if at least one stored trouble ticket is located, the incoming call is transferred to a help desk agent.

7. The method of claim 5 wherein, if no stored trouble ticket is located, an automated diagnostic procedure is initiated with the user over an interactive voice response mechanism.

8. A computer program product for using alarm data correlation to automatically analyze a network outage, the computer program product comprising a storage medium readable by a processing circuit and storing instructions for execution by the processing circuit for facilitating a method comprising:
receiving alarm data for a communications network;
correlating the received alarm data to determine a number of users affected by the outage;
applying a set of rules to the correlated alarm data to identify at least one root cause for the outage, and to determine whether or not a trouble ticket will be automatically generated for the outage.

9. The computer program product of claim 8 wherein the root cause includes at least one of:
a cut or broken communication cable;
an inoperative wireless communication link;
failed network equipment;
a failed satellite link; or
a natural disaster that disables equipment at one or more central offices or CLLIs or both.

10. The computer program product of claim 8 wherein the set of rules specify that a trouble ticket will be generated if an outage affects at least a predetermined number of users, or if an outage is determined to be a high impact outage, or both.

11. The computer program product of claim 10 wherein a high impact outage is an outage that is caused by at least one failed line card in DSLAM or BRAS equipment, or at least one failed asynchronous transfer mode (ATM) card in an ATM switch, or both.

12. The computer program product of claim 8 further including instructions for receiving an incoming call from a communications network user requesting help, and searching a network outage database to locate any stored trouble tickets.

13. The computer program product of claim 12 wherein, if at least one stored trouble ticket is located, the incoming call is transferred to a help desk agent.

14. The computer program product of claim 12 wherein, if no stored trouble ticket is located, an automated diagnostic procedure is initiated with the user over an interactive voice response mechanism.

15. A system for using alarm data correlation to automatically analyze a network outage, the system including:
an alarm analysis mechanism for receiving alarm data associated with a communications network, wherein the alarm analysis mechanism is capable of correlating the received alarm data to determine a number of users affected by the outage, applying a set of rules to the correlated alarm data to identify at least one root cause for the outage, and determining whether or not a trouble ticket will be automatically generated for the outage based upon the identified root cause;
a rules database for storing the set of rules, wherein the rules database is operably coupled to the alarm analysis mechanism;
an alarm database for storing alarm data, wherein the alarm database is operably coupled to the alarm analysis mechanism;
at least one of a user network interface database operably coupled to the alarm analysis mechanism, a network topology database operably coupled to the alarm analysis mechanism, or a telephone number to common language location identifier (CLLI) database operably coupled to the alarm analysis mechanism, wherein the user network interface database stores data associating each of a plurality of user identifiers with one or more corresponding network interface equipment identifiers, the network topology database stores a set of attributes associated with each of a plurality of network elements, and the telephone number to CLLI mapping database associates each of a plurality of respective telephone numbers with a corresponding CLLI; and
a trouble ticket output mechanism operatively coupled to the alarm analysis mechanism and capable of at least one of printing a generated trouble ticket or displaying a generated trouble ticket.

16. The system of claim 15 wherein the root cause includes at least one of:
a cut or broken communication cable;
an inoperative wireless communication link;
failed network equipment;
a failed satellite link; or
a natural disaster that disables equipment at one or more central offices or CLLIs or both.

17. The system of claim 15 wherein the set of rules specify that a trouble ticket will be generated if an outage affects at least a predetermined number of users, or if an outage is determined to be a high impact outage, or both.

18. The system of claim 17 wherein a high impact outage is an outage that is caused by at least one failed line card in DSLAM or BRAS equipment, or at least one failed asynchronous transfer mode (ATM) card in an ATM switch, or both.

19. The system of claim 15 further including an interactive voice response mechanism for receiving an incoming call from a communications network user requesting help, and wherein the alarm analysis mechanism is capable of searching a network outage database to locate any stored trouble tickets.

20. The system of claim 19 wherein, if the alarm analysis mechanism locates at least one stored trouble ticket, the interactive voice response mechanism transfers the incoming call to a help desk agent.

21. The system of claim 19 wherein, if no stored trouble ticket is located, the interactive voice response mechanism initiates an automated diagnostic procedure with the user.
